(19) United States
(12) Patent Application Publication
(10) Pub. No.: US 2025/0048768 A1
(43) Pub. Date: Feb. 6, 2025

(54) SEMICONDUCTOR DEVICE, ELECTRONIC EQUIPMENT, AND WAFER

(71) Applicant: SONY SEMICONDUCTOR SOLUTIONS CORPORATION, Kanagawa (JP)

(72) Inventors: Nobutoshi FUJII, Kanagawa (JP); Kengo KOTOO, Kanagawa (JP)

(73) Assignee: SONY SEMICONDUCTOR SOLUTIONS CORPORATION, Kanagawa (JP)

(21) Appl. No.: 18/716,464

(22) PCT Filed: Oct. 28, 2022
(86) PCT No.: PCT/JP2022/040523

§ 371 Date: Jun. 4, 2024

(30) Foreign Application Priority Data
Dec. 13, 2021 (JP) 2021-201604

(51) Int. Cl. H01L 27/146

(52) U.S. Cl. CPC H01L 27/14634; H01L 27/14632; H01L 27/14636

(57) ABSTRACT

A semiconductor device with which the stacking of connection pads is unlikely to be significantly misaligned is provided. The semiconductor device includes two semiconductor layers, and a wiring layer on one side in a stacking direction and a wiring layer on the other side in the stacking direction that are interposed between the semiconductor layers, each including a plurality of sets located in an insulating film, the sets each including a connection pad, a wiring line, and a via connecting the connection pad to the wiring line, and that are electrically connected to each other by bonding bonding surfaces of the connection pads to each other. In all the sets in the wiring layer on one side in the stacking direction, a center of the connection pad is located at a first distance from a center of the via in a first direction.

### TECHNICAL FIELD

The present technology (technology relating to the present disclosure) relates to a semiconductor device, electronic equipment, and a wafer, and in particular to a semiconductor device, electronic equipment, and a wafer formed by bonding wafers together.

### BACKGROUND ART

Regarding a technology for bonding wafers (substrates) together, PTL 1 discloses forming a substrate having a Silicon on Insulator (SOI) structure by bonding substrates together, for example. More specifically, PTL 1 discloses that the center portions of two substrates are brought into contact with each other and bonded together with one of the substrates held in a convex shape. This limits entry of air bubbles between the substrates.

### CITATION LIST

### Patent Literature

PTL 1: JP3321827B

### SUMMARY

### Technical Problem

When wafers are bonded together through hybrid bonding, the wafers are electrically connected to each other by bonding the connection pads provided in one wafer to the connection pads provided in the other wafer. However, when wafers are bonded together with one of the wafers warped, one of the wafers may expand more in the radial direction than the other wafer.

An object of the present technology is to provide a semiconductor device, electronic equipment, and a wafer with which the stacking of connection pads is unlikely to be significantly misaligned.

### Solution to Problem

A semiconductor device according to one aspect of the present technology includes: two semiconductor layers; and a wiring layer on one side in a stacking direction and a wiring layer on the other side in the stacking direction that are interposed between the semiconductor layers, each including a plurality of sets located in an insulating film, the sets each including a connection pad, a wiring line, and a via connecting the connection pad to the wiring line, and that are electrically connected to each other by bonding bonding surfaces of the connection pads to each other, and in all the sets in the wiring layer on one side in the stacking direction, a center of the connection pad is located at a first distance from a center of the via in a first direction.

Electronic equipment according to one aspect of the present technology includes a photodetection device and an optical system configured to form an image of imaging light from a subject on the photodetection device, and one of the two semiconductor layers includes a photoelectric conversion portion capable of performing photoelectric conversion on incident light.

A wafer according to one aspect of the present technology includes: a laminate including a semiconductor layer and a wiring layer stacked on the semiconductor layer; and a plurality of chip regions that are arranged in a matrix in plan view on the laminate, each of the chip regions including an integrated circuit fabricated therein, wherein the wiring layer includes, for each of the chip regions, a plurality of sets that are provided in an insulating film and form a part of the integrated circuit, each of the sets including a connection pad, a wiring line, and a via connecting the connection pad to the wiring line, for each of the chip regions, a center of the connection pad is at a first distance from a center of the via in a first direction, and the first direction is a direction toward a center or an edge of the laminate in plan view.

### BRIEF DESCRIPTION OF DRAWINGS

FIG. 1A is a diagram showing a state before wafers according to a first embodiment of the present technology are bonded to each other.

FIG. 1B is a diagram showing bonded wafers according to the first embodiment of the present technology.

FIG. 2 is a chip layout diagram showing a configuration example of a photodetection device according to the first embodiment of the present technology.

FIG. 3 is a block diagram showing a configuration example of the photodetection device according to the first embodiment of the present technology.

FIG. 4 is an equivalent circuit diagram of a pixel of the photodetection device according to the first embodiment of the present technology.

FIG. 5 is a longitudinal cross-sectional view showing a cross-sectional configuration of the photodetection device according to the first embodiment of the present technology.

FIG. 6A is a diagram showing a configuration of the bonding surface of a first wafer with respect to a second wafer in a state in which the third wafer shown in FIG. 1B is viewed through from direction A.

FIG. 6B is a longitudinal cross-sectional view showing a cross-sectional configuration of a chip region taken along section line B-B in FIG. 6A.

FIG. 6C is a longitudinal cross-sectional view showing a cross-sectional configuration of a chip region taken along section line C-C in FIG. 6A.

FIG. 6D is a diagram schematically showing one row in the X direction including the chip region in the wafer center of the chip regions of FIG. 6A.

FIG. 7 is a step cross-sectional view showing a method for manufacturing a photodetection device according to the first embodiment of the present technology.

FIG. 8 is a longitudinal cross-sectional view showing a cross-sectional configuration of the main part of a photodetection device according to a second embodiment of the present technology.

FIG. 9A is a longitudinal cross-sectional view showing a cross-sectional configuration of the main part of a photodetection device according to a third embodiment of the present technology.

FIG. 9B is a diagram showing a configuration of the bonding surface of a second wafer with respect to a first wafer in a state in which a third wafer after bonding according to the third embodiment is viewed through from a direction perpendicular to the bonding surface.

FIG. 10 is a step cross-sectional view showing a method for manufacturing a photodetection device according to the third embodiment of the present technology.

FIG. 11 is a longitudinal cross-sectional view showing a cross-sectional configuration of the main part of a photodetection device according to a fourth embodiment of the present technology.

FIG. 12 is a diagram showing a schematic configuration of electronic equipment.

FIG. 13 is a block diagram showing an example of a schematic configuration of a vehicle control system.

FIG. 14 is an explanatory diagram showing an example of the installation positions of a vehicle outside information detection portion and an imaging portion.

FIG. 15 is a diagram showing an example of a schematic configuration of an endoscopic surgery system.

FIG. 16 is a block diagram showing an example of the functional configuration of a camera head and a CCU.

FIG. 17A is a diagram showing a conventional method for bonding wafers together.

FIG. 17B is a diagram showing conventional bonded wafers.

### DESCRIPTION OF EMBODIMENTS

Referring to the drawings, a preferred embodiment for carrying out the present technology is now described. Note that the embodiment described below is an example of a typical embodiment of the present technology, and this does not narrow the interpretation of the scope of the present technology.

In the following description of the drawings, the same or similar parts are denoted by the same or similar reference numerals. However, it should be noted that the drawings are schematic, and the relationship between thickness and planar dimensions, the thickness ratio of layers, and the like differ from the actual states. As such, the specific thickness and dimensions should be determined taking into account the following description. Also, some dimensional relationships and ratios may inevitably vary between the drawings.

Furthermore, first to sixth embodiments described below are examples of devices and methods for embodying the technical ideas of the present technology, and the technical ideas of the present technology do not specify the materials, shapes, structures, arrangements, and the like of the components to those described below. Various modifications may be made to the technical ideas of the present technology within the technical scope defined by the claims.

The description will be given in the following order.
1. First Embodiment
2. Second Embodiment
3. Third Embodiment
4. Fourth Embodiment
5. Fifth Embodiment
6. Sixth Embodiment
Example of Application to Electronic Equipment
Example of Application to Moving Object
Example of Application to Endoscopic Surgery System

### First Embodiment

In the present embodiment, an example in which the present technology is applied to a photodetection device, which is a semiconductor device, is described. More specifically, an example is described in which the present technology is applied to a photodetection device that is a back-illuminated complementary metal oxide semiconductor (CMOS) image sensor.

### Overview

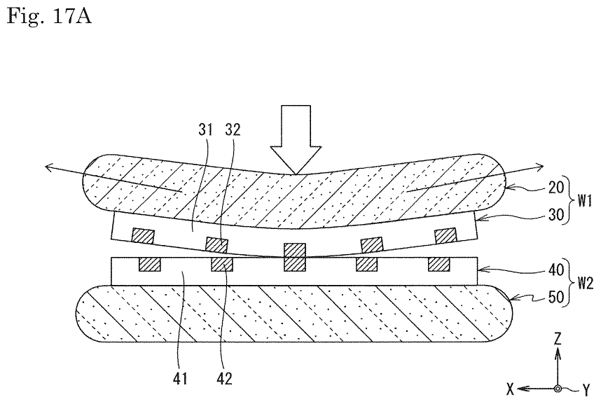

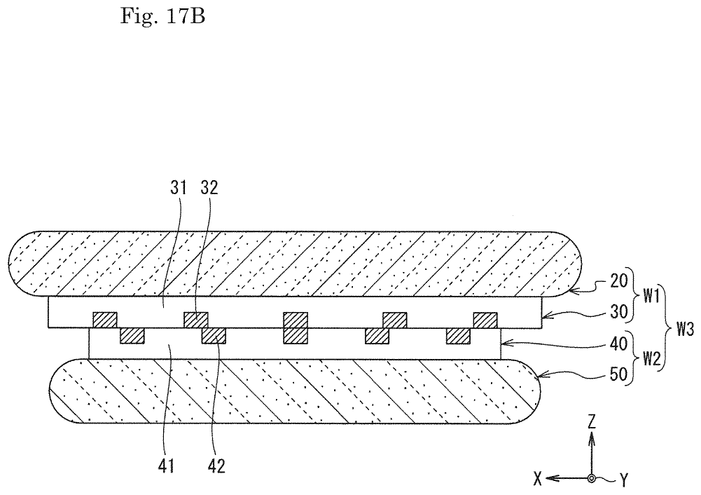

First, an overview of the present technology is described. FIGS. 17A and 17B are diagrams schematically illustrating conventional bonding between wafers (Wafer on Wafer, WoW). Referring to FIGS. 17A and 17B, a method is described in which a third wafer W3 is obtained by bonding a first wafer W1, which includes first semiconductor layer 20 and a first wiring layer 30 stacked on the first semiconductor layer 20, to a second wafer W2, which includes a second semiconductor layer 50 and a second wiring layer 40 stacked on the second semiconductor layer 50.

As shown in FIG. 17A, the first wafer W1 and the second wafer W2 are first placed opposed to each other with a gap therebetween such that their wiring layers face each other, and the wafers are positioned relative to each other. Then, the center portion of the first wafer W1, which is warped convexly toward the second wafer W2, is pressed, and the first wafer W1 is bonded to the second wafer W2 from the wafer center portion. The third wafer W3 including the first wafer W1 and the second wafer W2 is thus obtained. Here, the first wafer W1 is pressed in a warped state while being affixed, so that it expands in the radial direction and its dimensions increase in the radial direction. Consequently, as shown in FIG. 17B, although a first connection pad 32 provided in the first wiring layer 30 and a second connection pad 42 provided in the second wiring layer 40 are stacked and bonded in the center portion of the third wafer W3, the stacking of a first connection pad 32 and a second connection pad 42 may be significantly misaligned in a portion near the edge of the third wafer W3.

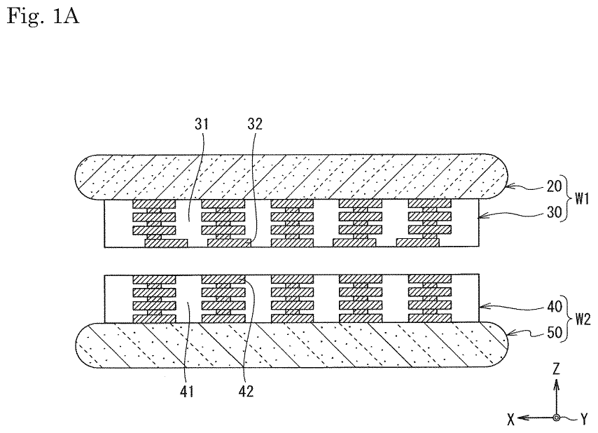

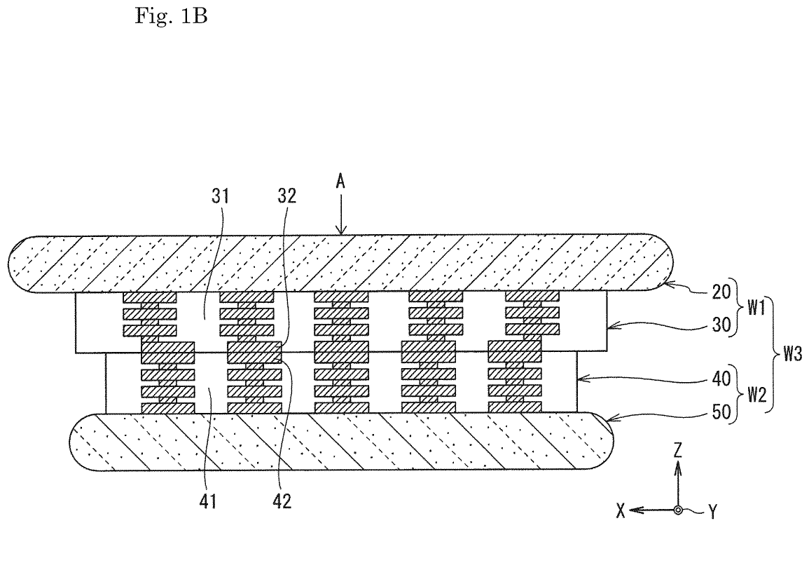

In contrast, in a wafer according to the first embodiment of the present technology, as shown in FIG. 1A, first connection pads 32 are provided closer to the center of the first wafer W1 in plan view in advance. Thus, as shown in FIG. 1B, even when the first wafer W1 and the second wafer W2 are bonded together using the same method, it is possible to limit significant misalignment of a first connection pad 32 and a second connection pad 42 in the portion near the edge of the third wafer W3.

### <<Overall Configuration of Photodetection Device>>

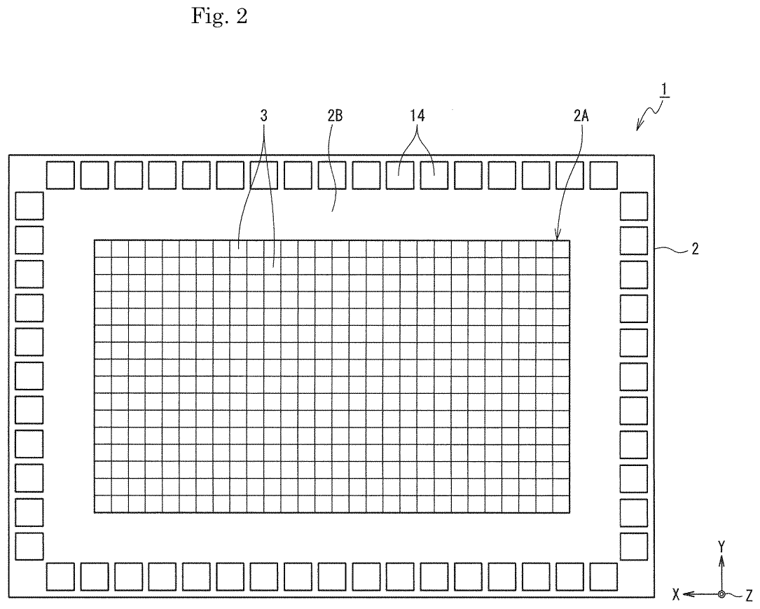

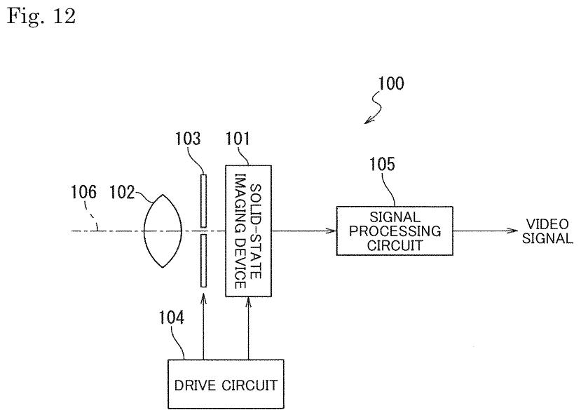

First, the overall configuration of the photodetection device 1 is described. The photodetection device 1 is a semiconductor device. As shown in FIG. 2, the photodetection device 1 according to the first embodiment of the present technology is mainly composed of a semiconductor chip 2 having a rectangular two-dimensional planar shape in plan view. That is, the photodetection device 1 is mounted on the semiconductor chip 2. As shown in FIG. 12, this photodetection device 1 receives imaging light (incident light 106) from a subject via an optical system (optical lens) 102, converts the amount of incident light 106 focused on an imaging surface into an electrical signal on a pixel-by-pixel basis, and outputs it as a pixel signal.

As shown in FIG. 2, the semiconductor chip 2 on which the photodetection device 1 is mounted includes, in a two-dimensional plane having an X direction and a Y direction intersecting with each other, a rectangular pixel region 2A provided in the center portion and a peripheral region 2B provided outside the pixel region 2A so as to surround the pixel region 2A.

The pixel region 2A is a light receiving surface, which receives light collected by the optical system 102 shown in FIG. 12, for example. In the pixel region 2A, a plurality of pixels 3 are arranged in a matrix on a two-dimensional plane having the X direction and the Y direction. In other words, the pixels 3 are repeatedly arranged in each of the X direction and the Y direction intersecting with each other within a two-dimensional plane. In this embodiment, as an example, the X direction and the Y direction are perpendicular to each other. The direction perpendicular to both the X direction and the Y direction is the Z direction (thickness direction, stacking direction). A direction perpendicular to the Z direction is a horizontal direction.

As shown in FIG. 2, a plurality of electrode pads (bonding pads) 14 are arranged in the peripheral region 2B.

### <Logic Circuit>

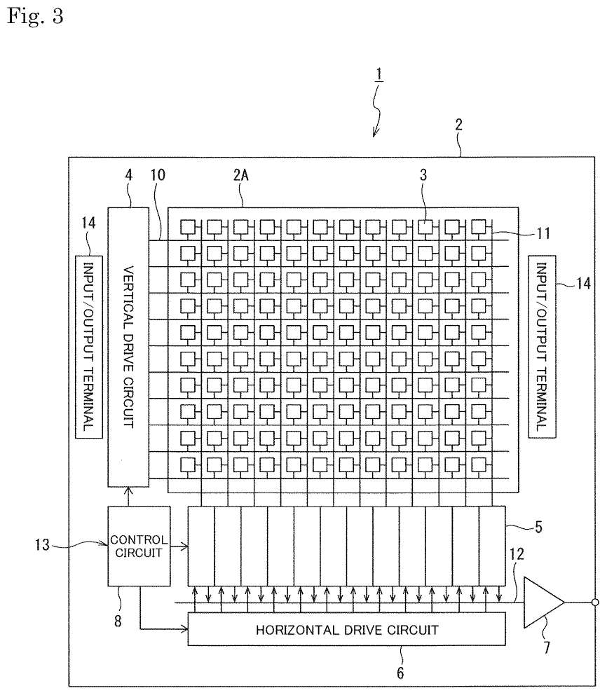

As shown in FIG. 3, the semiconductor chip 2 includes a vertical drive circuit 4, column signal processing circuits 5, a horizontal drive circuit 6, an output circuit 7, and a logic circuit 13 including a control circuit 8 and the like. The logic circuit 13 may be formed by a complementary MOS (CMOS) circuit having, as field effect transistors, n-channel conductivity type metal oxide semiconductor field effect transistors (MOSFET) and p-channel conductivity type MOSFET, for example.

The vertical drive circuit 4 may be formed by a shift register, for example. The vertical drive circuit 4 sequentially selects a desired pixel drive line 10, supplies a pulse to the selected pixel drive line 10 for driving pixels 3, and drives the pixels 3 row by row. That is, the vertical drive circuit 4 sequentially selects and scans pixels 3 in the pixel region 2A in the vertical direction on a row-by-row basis, and supplies pixel signals from the pixels 3 based on signal charges generated by the photoelectric conversion elements of the pixels 3 in accordance with the amount of received light to the column signal processing circuit 5 via the vertical signal lines 11.

The column signal processing circuits 5 are arranged for the respective columns of pixels 3, for example, and perform signal processing such as noise removal on signals output from the pixels 3 of one row for each pixel column. For example, the column signal processing circuits 5 perform signal processing such as correlated double sampling (CDS) and analog digital (AD) conversion to remove pixel-specific fixed pattern noise. A horizontal selection switch (not shown) is provided at the output stage of each column signal processing circuit 5 and connected between the output stage and the horizontal signal line 12.

The horizontal drive circuit 6 is formed by a shift register, for example. The horizontal drive circuit 6 sequentially outputs a horizontal scanning pulse to the column signal processing circuits 5 to select each column signal processing circuit 5 in turn, and causes the column signal processing circuits 5 to output pixel signals after signal processing to the horizontal signal line 12.

The output circuit 7 performs signal processing and outputs the pixel signals supplied sequentially from each of the column signal processing circuits 5 through the horizontal signal line 12. The signal processing may include, for example, buffering, black level adjustment, column variation correction, and various types of digital signal processing.

On the basis of the vertical synchronizing signal, the horizontal synchronizing signal, and the master clock signal, the control circuit 8 generates clock signals and control signals that serve as a reference for the operation of the vertical drive circuit 4, the column signal processing circuits 5, the horizontal drive circuit 6, and the like. The control circuit 8 then outputs the generated clock signals and control signals to the vertical drive circuit 4, the column signal processing circuit 5, the horizontal drive circuit 6, and the like.

### <Pixels>

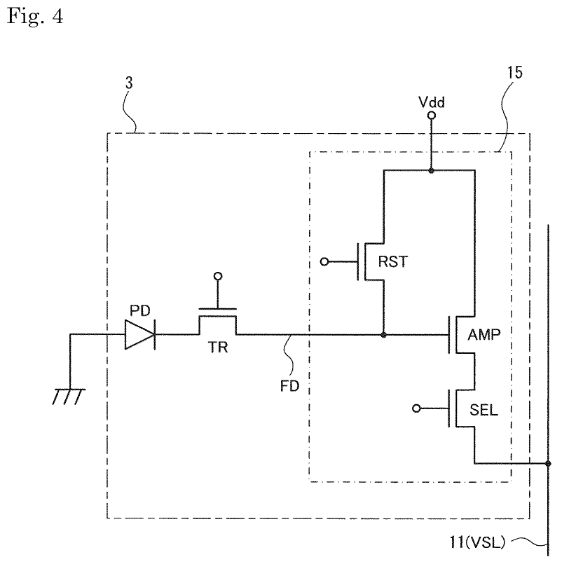

FIG. 4 is an equivalent circuit diagram showing an example of the configuration of the pixel 3. The pixel 3 includes a photoelectric conversion element PD, a charge storage region (floating diffusion) FD, which stores (holds) the signal charge photoelectrically converted by the photoelectric conversion element PD, and a transfer transistor TR, which transfers the signal charge photoelectrically converted by the photoelectric conversion element PD to the charge storage region FD. The pixel 3 also includes a readout circuit 15 electrically connected to the charge storage region FD.

The photoelectric conversion element PD generates a signal charge according to the amount of received light. The photoelectric conversion element PD also temporarily stores (holds) the generated signal charge. The photoelectric conversion element PD has a cathode side electrically connected to the source region of the transfer transistor TR, and an anode side electrically connected to a reference potential line (such as the ground). For example, a photodiode may be used as the photoelectric conversion element PD.

The drain region of the transfer transistor TR is electrically connected to the charge storage region FD. The gate electrode of the transfer transistor TR is electrically connected to a transfer transistor drive line among the pixel drive lines 10 (see FIG. 3).

The charge storage region FD temporarily stores and holds the signal charge transferred from the photoelectric conversion element PD via the transfer transistor TR.

The readout circuit 15 reads out the signal charges stored in the charge storage region FD, and outputs a pixel signal based on the signal charges. The readout circuit 15 may include, but not limited to, an amplification transistor AMP, a selection transistor SEL, and a reset transistor RST, as pixel transistors. These transistors (AMP, SEL, RST) are each formed by a MOSFET including a gate insulating film made of a silicon oxide film (SiO₂ film), a gate electrode, and a pair of main electrode regions that function as a source region and a drain region, for example. Furthermore, these transistors may be metal insulator semiconductor FETs (MISFETs) whose gate insulating film is made of a silicon nitride film (Si₃N₄ film) or a laminated film of a silicon nitride film and a silicon oxide film.

The amplification transistor AMP has a source region electrically connected to the drain region of the selection transistor SEL, and a drain region electrically connected to the power supply line Vdd and the drain region of the reset transistor. The gate electrode of the amplification transistor AMP is electrically connected to the charge storage region FD and the source region of the reset transistor RST.

The selection transistor SEL has a source region electrically connected to the vertical signal line 11 (VSL) and a drain electrically connected to the source region of the amplification transistor AMP. The gate electrode of the selection transistor SEL is electrically connected to a selection transistor drive line among the pixel drive lines 10 (see FIG. 3).

The reset transistor RST has a source region electrically connected to the charge storage region FD and the gate electrode of the amplification transistor AMP, and a drain region electrically connected to the power supply line Vdd and the drain region of the amplification transistor AMP. The gate electrode of the reset transistor RST is electrically connected to a reset transistor drive line among the pixel drive lines 10 (see FIG. 3).

### <<Specific Configuration of Photodetection Device>>

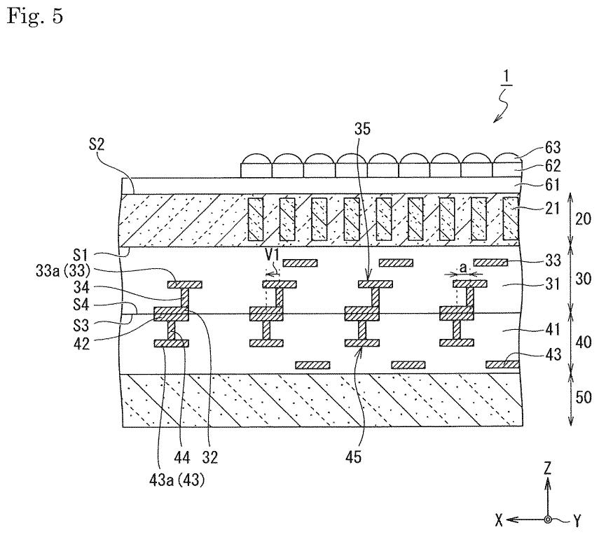

Referring to FIG. 5, a specific configuration of the photodetection device 1 is now described.

### <Laminate Structure of Photodetection Device>

The photodetection device 1 (semiconductor chip 2) has a laminate structure in which a first semiconductor layer 20, which includes a first surface S1 and a second surface S2 located opposite each other, a first wiring layer 30, a second wiring layer 40, and a second semiconductor layer 50 are stacked in this order.

Furthermore, the photodetection device 1 (semiconductor chip 2) includes, but not limited to, a laminate structure in which an insulating film 61, a color filter 62, and an on-chip lens 63 are layered in this order on the second surface S2. The insulating film 61 may be made of, but not limited to, silicon oxide (SiO₂), for example. The insulating film 61 also functions as a planarizing film. The color filter 62 and the on-chip lens 63 are provided for each pixel 3. The color filter 62 and the on-chip lens 63 may be made of a resin material, for example. The incident light passes through the on-chip lens 63 and is collected on the photoelectric conversion portion 21 described below. The color filter 62 separates the light incident on the first semiconductor layer 20 into different colors.

### <First Semiconductor Layer>

The first semiconductor layer 20 (semiconductor layer) is formed by a semiconductor substrate. The first semiconductor layer 20 is formed by, but not limited to, a single crystal silicon substrate. More specifically, the first semiconductor layer 20 is formed by, but not limited to, a single crystal silicon substrate of a first conductivity type (for example, p-type). The second surface S2 of the first semiconductor layer 20 may be referred to as a light incident surface or a back surface, and the first surface S1 may be referred to as an element formation surface or a main surface. Furthermore, in the section of first semiconductor layer 20 corresponding to the pixel region 2A, a semiconductor region 21 of a second conductivity type (for example, n-type) is provided for each pixel 3. In this manner, the photoelectric conversion element PD shown in FIG. 4 is formed for each pixel 3. In this embodiment, the semiconductor region 21 is referred to as a photoelectric conversion portion 21. The photoelectric conversion portion 21 is capable of performing photoelectric conversion on the incident light incident from the second surface S2. The photoelectric conversion portions 21 may be separated from each other by a known isolation region (not shown). The isolation region may be, but not limited to, impurity isolation or trench isolation, for example. Also, in the pixel region of the first semiconductor layer 20, elements such as a charge storage region FD, a transfer transistor TR, and a transistor forming a readout circuit 15 shown in FIG. 4, although not limited thereto, may be formed for each pixel 3, for example. The number of pixels 3 is not limited to that shown in FIG. 5.

### <First Wiring Layer>

The first wiring layer 30 is a wiring layer on one side in the stacking direction. The first wiring layer 30 includes an insulating film 31, first connection pads 32, wiring lines 33, and vias 34. The first connection pads 32, the wiring lines 33, and the vias 34 are provided in the insulating film 31. More specifically, the first connection pads 32 and the wiring lines 33 are stacked with the insulating film 31 interposed therebetween. The first connection pads 32 are at a third surface S3 of the first wiring layer 30 (the surface of the first wiring layer 30 opposite to the side corresponding to the first semiconductor layer 20). The surface of each first connection pad 32 at the third surface S3 is referred to as a bonding surface. The vias 34 connect the first connection pads 32 to the wiring lines 33. The wiring lines 33 connected to the first connection pads 32 through the vias 34 are referred to as wiring lines 33a to distinguish them from the other wiring lines 33. When no distinction is made, they are simply called wiring lines 33. The vias 34 are provided at positions where the first connection pads 32 and the wiring lines 33a overlap in plan view. The first wiring layer 30 also includes a plurality of sets 35 of a first connection pad 32, a wiring line 33a, a via 34 connecting the first connection pad 32 to the wiring line 33a.

In all sets 35 of the first wiring layer 30, the center of the first connection pad 32 in plan view is located at distance a from the center of the via 34 in plan view to the left of the drawing plane. The position of the center of the first connection pad 32 in plan view from the center of the via 34 in plan view is represented by vector V1 in the figure. The direction of vector V1 represents a first direction (the left direction of the drawing plane in the example of FIG. 5), and the magnitude of vector V1 represents a first distance (distance a in the example of FIG. 5). The direction and magnitude of vector V1 may be different in another photodetection device. This will be described below in the description of wafers.

The insulating film 31 is made of silicon oxide, for example, although it is not limited to this. The first connection pad 32 is made of a metal. More specifically, examples of the metal forming the first connection pad 32 include, but are not limited to, copper (Cu) and aluminum (Al). The via 34 is made of a metal. More specifically, examples of the metal forming the vias 34 include, but are not limited to, copper (Cu), aluminum (Al), tungsten (W), and the like. The wiring line 33 is made of a metal. More specifically, examples of the metal forming the wiring line 33 include, but are not limited to, copper (Cu), aluminum (Al), and the like.

### <Second Wiring Layer>

The second wiring layer 40 is a wiring layer on the other side in the stacking direction. The second wiring layer 40 includes an insulating film 41, second connection pads 42, wiring lines 43, and vias 44. The second connection pads 42, the wiring lines 43, and the vias 44 are provided in the insulating film 41. More specifically, the second connection pads 42 and the wiring lines 43 are stacked with the insulating film 41 interposed therebetween. The second connection pads 42 are at a fourth surface S4 of the second wiring layer 40 (the surface of the second wiring layer 40 opposite to the side corresponding to the second semiconductor layer 50). The surface of each second connection pad 42 at the fourth surface S4 is referred to as a bonding surface. The bonding surface of the second connection pad 42 is bonded to the bonding surface of the first connection pad 32. The vias 44 connects the second connection pads 42 to the wiring lines 43. The wiring lines 43 connected to the second connection pads 42 through the vias 44 are referred to as wiring lines 43a to distinguish them from the other wiring lines 43. When no distinction is made, they are simply called wiring lines 43. The second wiring layer 40 also includes a plurality of sets 45 of a second connection pad 42, a wiring line 43a, a via 44 connecting the second connection pad 42 to the wiring line 43a. The above-mentioned distance a is set to be greater than the distance between the center of the second connection pad 42 in plan view and the center of the via 44 in plan view. The center of the second connection pad 42 in plan view is designed to coincide with the center of the via 44 in plan view, and they coincide within the range of manufacturing variation. All sets 45 in the second wiring layer 40 are configured in the same manner.

The insulating film 41 may be made of, but not limited to, silicon oxide, for example. The second connection pad 42 is made of a metal. More specifically, examples of the metal forming the second connection pad 42 include, but are not limited to, copper (Cu) and aluminum (Al). The via 44 is made of a metal. More specifically, examples of the metal forming the vias 44 include, but are not limited to, copper (Cu), aluminum (Al), tungsten (W), and the like. The wiring 43 is made of a metal. More specifically, examples of the metal forming the wiring line 43 include, but are not limited to, copper (Cu), aluminum (Al), and the like.

### <Second Semiconductor Layer>

The second semiconductor layer 50 (semiconductor layer) is formed by a semiconductor substrate. The second semiconductor layer 50 is formed by, but not limited to, a single crystal silicon substrate. More specifically, the second semiconductor layer 50 is formed by, but not limited to, a single crystal silicon substrate of a first conductivity type (for example, p-type). The second semiconductor layer 50 includes, but not limited to, elements such as transistors forming the logic circuit 13.

### <<Wafer>>

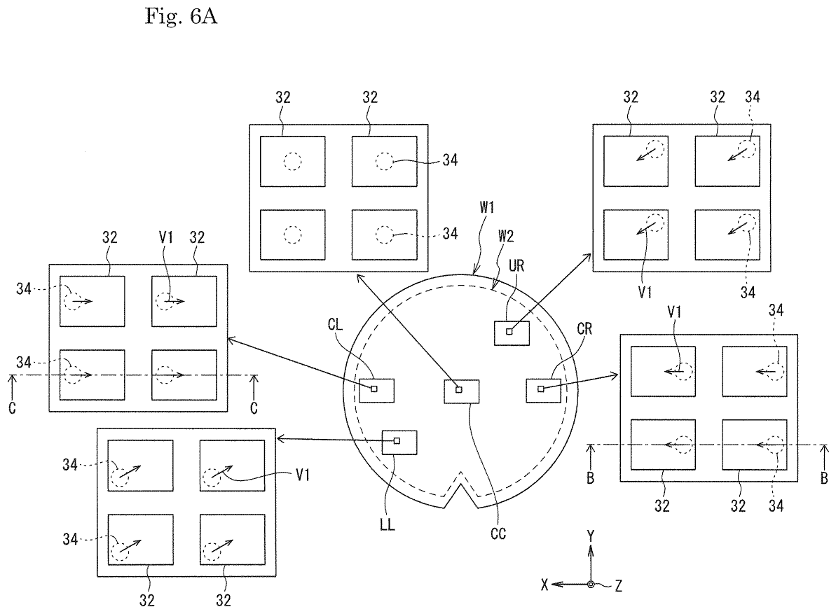

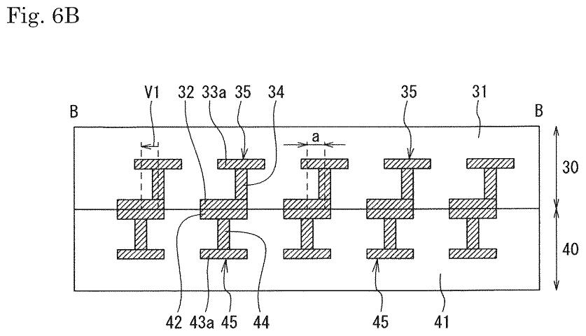

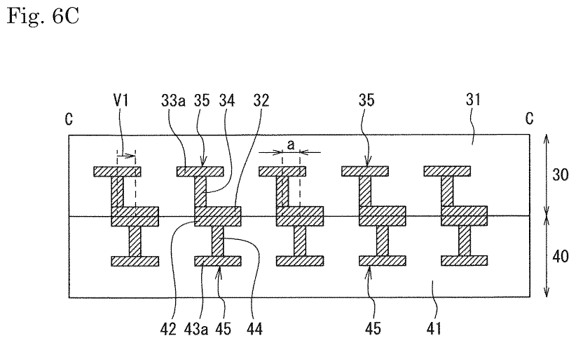

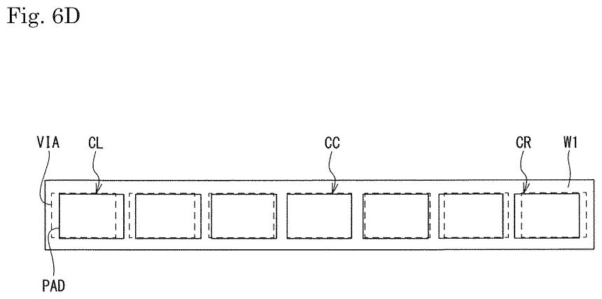

Referring to FIGS. 1B and 6A to 6D, a third wafer W3 is now described. The third wafer (wafer) W3 includes a first wafer (wafer) W1 and a second wafer W2. The first wafer W1 includes a laminate of a first semiconductor layer (semiconductor layer) 20 and a first wiring layer (wiring layer) 30 stacked on the first semiconductor layer 20, and the second wafer W2 includes a laminate of a second semiconductor layer (semiconductor layer) 50 and a second wiring layer (wiring layer) 40 stacked on the second semiconductor layer 50. The third wafer W3 includes a plurality of chip regions. In one chip region, an integrated circuit forming the main portion of one photodetection device 1 is fabricated. The chip regions are partitioned by scribe lines (dicing regions) and are repeatedly arranged in both the X and Y directions with the scribe lines interposed between one another. That is, a plurality of chip regions are arranged in a matrix on the X-Y plane of the third wafer W3, and the third wafer W3 has a plurality of photodetection devices 1 (integrated circuits) before being divided into individual pieces. More specifically, the integrated circuits are fabricated separately on the first wafer W1 and the second wafer W2. Also, sets 35 and 45 form a part of an integrated circuit.

FIG. 6A is a diagram showing the configuration of the bonding surface of the first wafer W1 with respect to the second wafer W2 in a state in which the third wafer W3 shown in FIG. 1B is viewed through from direction A. As shown in the figure, the first wafer W1 has a larger amount of expansion due to bonding than the second wafer W2. The wafer shown in FIG. 6A shows some of the chip regions mentioned above. The chip region CC is located at the center of the first wafer W1 in both the Y and X directions. The chip region CR is located in the center in the Y direction and on the right side of the drawing plane in the X direction. The chip region CL is located in the center in the Y direction and on the left side of the drawing plane in the X direction. The chip region UR is located on the upper side of the drawing plane in the Y direction and on the right side of the drawing plane in the X direction. The chip region LL is located on the lower side of the drawing plane in the Y direction and on the left side of the drawing plane in the X direction. FIG. 6A also shows an enlarged view of some of the first connection pads 32 and vias 34 (four of each in FIG. 6A) formed in the chip regions CC, CR, CL, UR, and LL.

In the chip region CC, the center of the first connection pad 32 coincides with the center of the via 34 in plan view, whereas in the chip regions CR, CL, UR, and LL, the center of the first connection pad 32 is at a position separated from the center of the via 34 by vector V1. The direction of vector V1 represents a first direction, and the magnitude thereof represents a first distance. Within one chip region, the directions and magnitudes of vectors V1 are identical. Different chip regions have vectors V1 that are different in direction and magnitude. That is, each chip region has a unique vector V1. As such, in photodetection devices 1 (semiconductor chips 2) obtained by separating chip regions, at least one of the direction and the magnitude of vector V1 may differ. Also, vector V1 of each chip region other than the chip region CC is directed toward the center of the first wafer W1 in plan view. For example, in the chip region CR, the direction of vector V1 is to the left of the drawing plane toward the center of the first wafer W1, and in the chip region CL, the direction of vector V1 is to the right of the drawing plane toward the center of the first wafer W1. The direction of vector V1 is radially directed from the wafer edge toward the wafer center in plan view. The direction of vector V1 is opposite to the direction in which the first wafer W1 expands during bonding. In the first wafer W1, which has a greater expansion amount than the second wafer W2, vector V1 is directed in the direction opposite to the expansion direction of the wafer.

A more detailed description is now given using the chip region CR and the chip region CL as examples. The chip regions CR and CL are located at the same position in the Y direction as the chip region CC, and are located at equal distances from the chip region CC in the X direction, with the chip region CC located therebetween. In a longitudinal cross-sectional view of the chip region CR of the third wafer W3 taken along section line B-B in FIG. 6A, as shown in FIG. 6B, in all sets 35 of the first wiring layer 30, the center of the first connection pad 32 is located at distance a from the center of the vias 34 to the left of the drawing plane toward the center of the first wafer W1 in plan view. The photodetection device 1 shown in FIG. 5 corresponds to a semiconductor chip 2 obtained by separating the chip region CR into a piece. In a longitudinal cross-sectional view of the chip region CL of the third wafer W3 taken along section line C-C in FIG. 6A, as shown in FIG. 6C, in all sets 35 of the first wiring layer 30, the center of the first connection pad 32 is located at distance a from the center of the vias 34 to the right of the drawing plane toward the center of the first wafer W1 in plan view. In both FIGS. 6B and 6C, the above-mentioned distance a is set to be greater than the distance between the center of the second connection pad 42 in plan view and the center of the via 44 in plan view. FIGS. 6B and 6C schematically show the insulating film 31, the insulating film 41, the sets 35, and the sets 45 of the third wafer W3, and the other components are omitted. In the following, components are similarly omitted in similar drawings.

FIG. 6D is a schematic view of one row in the X direction including the chip region CC among the chip regions of the first wafer W1. The number of chip regions in one column is not limited to that shown in FIG. 6D. The dashed lines indicate the chip regions VIA in the step of forming vias 34, and the solid lines indicate the chip regions PAD in the step of forming first connection pads 32. As shown in the figure, in the step of forming each first connection pad 32, the chip region PAD is offset toward the center of the first wafer W1, so that the center of the first connection pad 32 can be positioned at a first distance in a first direction from the center of the via 34 in plan view.

Furthermore, when bonding the first wafer W1 to the second wafer W2, the amount of expansion of the first wafer W1 relative to the second wafer W2 is grater at positions closer to the edge of the first wafer W1. That is, the amount of offset is greater at positions farther from the center of the first wafer W1. For this reason, a chip region PAD that is farther from the center of the first wafer W1 has a greater offset amount (first distance). In FIG. 6D, the first distance is exaggerated to facilitate understanding. Also, the dashed lines and solid lines are slightly deviated in the Y direction. This is to clearly illustrate the overlap between the dashed lines and solid lines. The dashed lines and the solid lines are actually at the same position in the Y direction within one row in the X direction that includes the chip region CC.

### <<Method for Manufacturing Photodetection Device>>

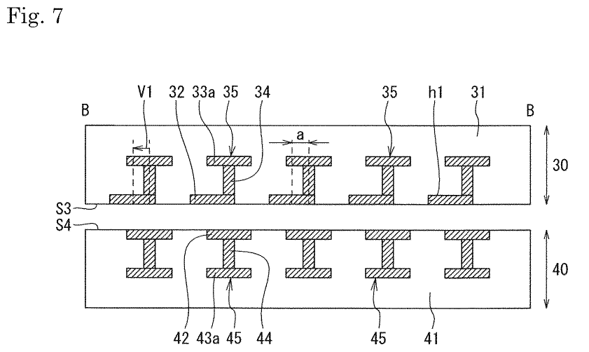

Referring to FIG. 7, a method for manufacturing the photodetection device 1 is now described. In the description of the manufacturing method, only the steps concerning the formation of the first connection pads 32 and the bonding of the first wafer W1 and the second wafer W2 are described. The other parts can be formed by using known methods, and the description thereof is thus omitted. FIG. 7 is a schematic diagram of the insulating film 31, insulating film 41, sets 35, and sets 45 that belong to the sections of the first wafer W1 and the second wafer W2 corresponding to the chip region CR, and other components are omitted. In the following, components are similarly omitted in similar drawings.

First, the first wafer W1 and the second wafer W2 are prepared. In preparing the first wafer W1, an integrated circuit is first fabricated for each chip region. After the fabrication of the main parts of the integrated circuits is completed, vias 34 are formed in the first wiring layer 30 of the first wafer W1 so as to be connected to the wiring lines 33a, and then first connection pads 32 are formed so as to be connected to the vias 34. The first connection pads 32 are formed such that their bonding surfaces are at the third surface S3. More specifically, the center of each first connection pad 32 in plan view is offset from the center of the via 34 in plan view by distance a toward the center of the first wafer W1 in plan view, more specifically to the left of the drawing plane, to form the first connection pad 32. Distance a, that is, the magnitude of vector V1, may be determined taking into account the amount by which the first wafer W1 expands, more specifically, the amount by which the first wafer W1 becomes larger than the second wafer W2. Each first connection pad 32 may be obtained, but not limited to, by stacking an insulating film 31 on the exposed surface of the first wiring layer 30, forming a hole h1 in the stacked insulating film 31 by known lithography and etching techniques, filling the hole h1 with copper by a plating method, and then removing excess copper by a chemical mechanical polishing (CMP) method and planarizing the exposed surface of the first wiring layer 30, for example.

As such, the offset of the center of the first connection pad 32 in plan view may be achieved by offsetting, in the lithography step that forms the hole h1, the imaging position of the exposure pattern from the originally intended imaging position in accordance with the direction and distance indicated by vector V1. That is, the exposure may be performed such that a plurality of exposure patterns within the wafer surface are offset toward the center of the first wafer W1 in plan view from the originally intended imaging positions. Furthermore, the magnitude of the first distance may be set to be greater for an exposure pattern that is farther from the center of the first wafer W1. Here, the originally intended imaging position is the imaging position where the center of the first connection pad 32 in plan view coincides with the center of the via 34 in plan view.

The second wafer W2 is prepared in the same manner as in a conventional method. Integrated circuits including sets 45 are formed on the prepared second wafer W2. The first wafer W1 and the second wafer W2 are placed opposed to each other with a gap therebetween such that their wiring layers face each other, and the wafers are positioned relative to each other. More specifically, the third surface S3 and the fourth surface S4 face each other, and the wafers are positioned relative to each other. At this time point, the first connection pads 32 are located closer to the center of the first wafer W1 in plan view (to the left of the drawing plane) than the second connection pads 42.

Then, the center portion of the first wafer W1, which is warped convexly toward the second wafer W2, is pressed, and the first wafer W1 is bonded to the second wafer W2 from the wafer center portion to obtain the state shown in FIG. 6B. At this time, of the first wafer W1 and the second wafer W2, at least the first wafer W1 expands in the radial direction. The amount of radial expansion of the first wafer W1 is greater than that of the second wafer W2. Here, in the first wafer W1, which is one of the first wafer W1 and second wafer W2 that has a greater amount of radial expansion, each first connection pad 32 is offset in advance toward the center of the wafer in plan view in anticipation of the expansion of the first wafer W1. Consequently, even when the first wafer W1 expands more in the radial direction than the second wafer W2, the amount of movement of the first connection pad 32 caused by the expansion of the first wafer W1 is offset by the offset amount. The first connection pad 32 thus moves to a position where the second connection pad 42 is present. As a result, the stacking of the first connection pad 32 and the second connection pad 42 is unlikely to be significantly misaligned.

### Main Advantageous Effects of First Embodiment

The main advantageous effects of the first embodiment are described below. With the photodetection device 1 according to the first embodiment of the present technology, in all sets 35 of the first wiring layer 30, the center of the first connection pad 32 is located at a first distance from the center of the via 34 in the first direction in plan view. As such, in the process of manufacturing the photodetection device 1 using WoW, even when the first wafer W1 expands in the radial direction and becomes greater in size than the second wafer W2 in the radial direction in the bonding between the first wafer W1 and the second wafer W2, the stacking of the first connection pad 32 and the second connection pad 42 is unlikely to be significantly misaligned. This limits degradation of the electrical connectivity between the wiring layers, more specifically, the electrical connectivity between the first wiring layer 30 and the second wiring layer 40.

Additionally, with the photodetection device 1 according to the first embodiment of the present technology, the first distance is set to be greater than the distance between the center of the second connection pad 42 and the center of the via 44 in plan view of each set 45 of the second wiring layer 40. As such, in the process of manufacturing the photodetection device 1 using WoW, even when the first wafer W1 expands in the radial direction and becomes greater in size than the second wafer W2 in the radial direction in the bonding between the first wafer W1 and the second wafer W2, the stacking of the first connection pad 32 and the second connection pad 42 is unlikely to be significantly misaligned. This limits degradation of the electrical connectivity between the wiring layers, more specifically, the electrical connectivity between the first wiring layer 30 and the second wiring layer 40.

Furthermore, as the pixels 3 become miniaturized and the numbers of the first connection pads 32 and the second connection pads 42 increase, control for bonding these bonding pads becomes more important. In the photodetection device 1 according to the first embodiment of the present technology, by applying the present technology to the pixel region 2A, it is possible to limit significant misalignment of the stacking of the first connection pads 32 and the second connection pads 42 of the pixels 3. This limits degradation of the electrical connectivity between the wiring layers even when the pixels 3 are miniaturized.

Also, in the photodetection device 1 according to the first embodiment of the present technology, the first wafer W1 includes a laminate including the first semiconductor layer 20 and the first wiring layer 30 stacked on the first semiconductor layer 20 and chip regions that are arranged in a matrix in plan view on the laminate and each include an integrated circuit fabricated therein. The first wiring layer 30 includes a plurality of sets 35 that are provided in the insulating film 31 and form a part of the integrated circuit for each chip region, and each set includes a first connection pad 32, a wiring line 33a, and a via 34 connecting the first connection pad 32 to the wiring line 33a. The center of the first connection pad 32 provided in one chip region is at the first distance from the center of the via 34 toward the center of the first wafer W1. In this manner, the first connection pads 32 of the first wafer W1 are provided closer to the center of the first wafer W1 in plan view before the wafers are bonded to each other. Thus, even when the first wafer W1 expands in the radial direction and becomes greater in size than the second wafer W2 in the radial direction in the bonding between the first wafer W1 and the second wafer W2, the stacking of the first connection pad 32 and the second connection pad 42 is unlikely to be significantly misaligned. This limits degradation of the electrical connectivity between the wiring layers, more specifically, the electrical connectivity between the first wiring layer 30 and the second wiring layer 40.

In the first embodiment described above, the first wafer W1 and the second wafer W2 are bonded together in a state in which the first wafer W1 is warped convexly toward the second wafer W2. However, the first wafer W1 and the second wafer W2 may be bonded together in a state in which the second wafer W2 is warped convexly toward the first wafer W1. Furthermore, the first wafer W1 and the second wafer W2 may be bonded together in a state in which both are warped convexly toward each other. In either case, a difference in the amount of expansion may occur between the first wafer W1 and the second wafer W2. In either case, the connection pads of the wafer that has a greater amount of expansion may be offset toward the center of the wafer in plan view.

### Second Embodiment

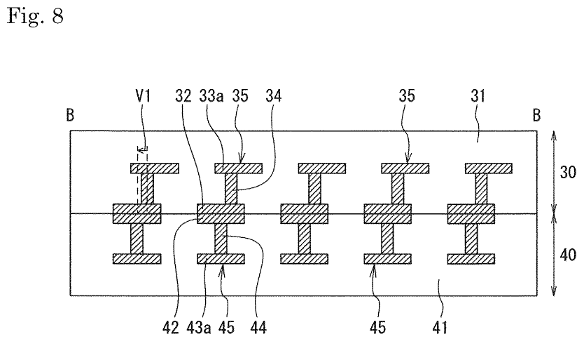

A second embodiment of the present technology shown in FIG. 8 is described below. The photodetection device 1 according to the second embodiment differs from the photodetection device 1 according to the first embodiment described above in that in all sets 35 of the first wiring layer 30, the vias 34 are offset relative to the wiring lines 33a in plan view. The other configuration of the photodetection device 1 is basically the same as that of the photodetection device 1 according to the first embodiment described above. Components that have already been described are given the same reference numerals and their description are omitted. The sets 35 and 45 of one photodetection device 1 shown in FIG. 8 are sets 35 and 45 in a cross-sectional view of the chip region CR in FIG. 6A and a photodetection device 1 obtained by separating the chip region CR taken along section line B-B.

### <Vias>

The vias 34 are provided at positions where the first connection pads 32 and the wiring lines 33a overlap in plan view. The vias 34 in FIG. 8 are provided to the left of the drawing plane compared to the vias 34 in FIG. 6B of the first embodiment. More specifically, each via 34 is offset in the same direction (first direction) as the first connection pad 32 relative to the wiring line 33a. As such, the stacking margin between the via 34 and the first connection pad 32 in FIG. 8 is greater than the stacking margin between the via 34 and the first connection pad 32 in FIG. 6B. This limits degradation of the accuracy of stacking between the vias 34 and the first connection pads 32 due to stacking variations.

### Main Advantageous Effects of Second Embodiment

The main advantageous effects of the second embodiment are described below. The photodetection device 1 according to the second embodiment also has the same advantageous effect as the photodetection device 1 according to the first embodiment described above.

### Third Embodiment

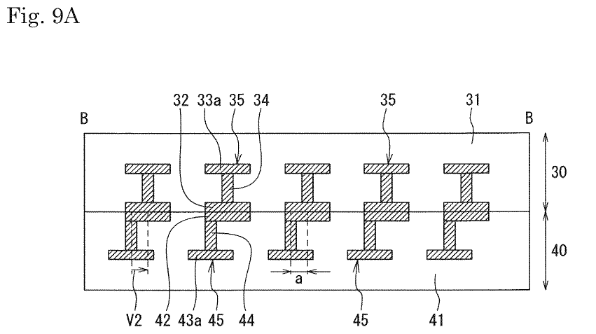

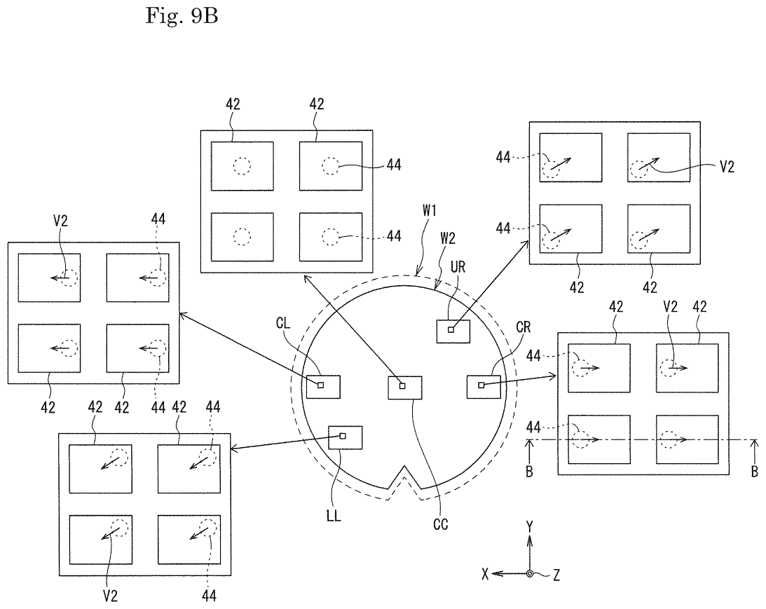

A third embodiment of the present technology shown in FIGS. 9A and 9B is described below. The photodetection device 1 of the third embodiment differs from the photodetection device 1 of the first embodiment described above in that in sets 45 instead of sets 35, the centers of the connection pads are offset from the centers of the vias. The other configuration of the photodetection device 1 is basically the same as that of the photodetection device 1 of the first embodiment described above. Components that have already been described are given the same reference numerals and their description are omitted. FIG. 9B is a diagram showing the configuration of the bonding surface of the second wafer W2 with respect to the first wafer W1 in a state in which the third wafer W3 after bonding is viewed through from a direction perpendicular to the bonding surface. The sets 35 and 45 of one photodetection device 1 shown in FIG. 9A are sets 35 and 45 in a cross-sectional view of the chip region CR in FIG. 9B and a photodetection device 1 obtained by separating the chip region CR taken along section line B-B.

### <First Wiring Layer>

The first wiring layer 30 is a wiring layer on the other side in the stacking direction. As shown in FIG. 9A, in one photodetection device 1, the center of the first connection pad 32 in plan view is designed to coincide with the center of the via 34 in plan view, and they coincide within the range of manufacturing variation. All sets 35 in the first wiring layer 30 are configured in the same manner.

### <Second Wiring Layer>

The second wiring layer 40 is a wiring layer on one side in the stacking direction. In all sets 45 of the second wiring layer (wiring layer) 40 in one photodetection device 1, the center of the second connection pad 42 in plan view is located at distance a to the right of the drawing plane from the center of the via 44 in plan view. The position of the center of the second connection pad 42 in plan view from the center of the via 44 in plan view is represented by vector V2 in the figure. The direction of vector V2 represents a first direction (the right direction of the drawing plane in the example of FIG. 9A), and the magnitude of vector V2 represents a first distance (distance a in the example of FIG. 9A). As in the first embodiment, the direction and magnitude of vector V2 may be different in another photodetection device. Also, the above-mentioned distance a is set to be greater than the distance between the center of the first connection pad 32 in plan view and the center of the via 34 in plan view. The vias 44 are provided at positions where the second connection pads 42 and the wiring lines 43a overlap in plan view.

### <<Wafer>>

Chip regions CC, CR, CL, UR, and LL are shown in the wafer of FIG. 9B. In the chip region CC, the center of the second connection pad 42 coincides with the center of the via 44 in plan view, whereas in the chip regions CR, CL, UR, and LL, the center of the second connection pad 42 is at a position separated from the center of the via 44 by vector V2. The direction of vector V2 represents a first direction, and the magnitude thereof represents a first distance. Within one chip region, the directions and magnitudes of vectors V2 are identical. Different chip regions have vectors V2 that are different in direction and magnitude. Also, vector V2 of each chip region other than the chip region CC is directed in the direction opposite to the center (direction toward the edge) in plan view of the second wafer W2. For example, in the chip region CR, the direction of vector V2 is to the right of the drawing plane toward the edge of the second wafer W2, and in the chip region CL, the direction of vector V2 is to the left of the drawing plane toward the edge of the second wafer W2. The direction of vector V2 is radially directed from the center of the wafer toward the edge of the wafer in plan view. The direction of vector V2 is the same as the direction in which the first wafer W1 expands during bonding. In the second wafer W2, which has a smaller expansion amount than the first wafer W1, vector V2 is oriented in the expansion direction of the wafer.

### <<Method for Manufacturing Photodetection Device>>

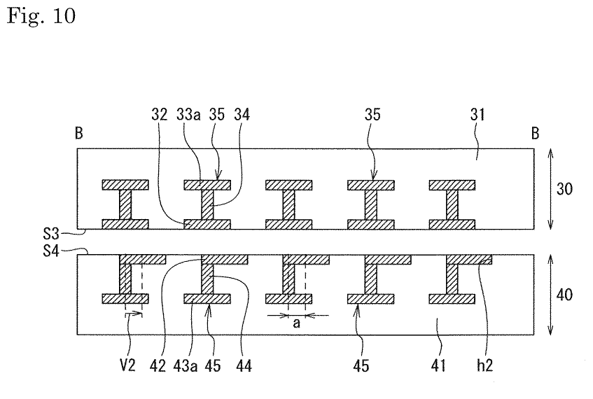

Referring to FIG. 10, a method for manufacturing the photodetection device 1 is now described. In this embodiment, the description focuses on the differences from the method for manufacturing the photodetection device 1 described in the first embodiment. In the description, the portions where the first wafer W1 can be read as the second wafer W2, and the first wafer W1 and related portions can be read as the second wafer W2 and related portions are omitted. FIG. 10 is a schematic diagram of the insulating film 31, insulating film 41, sets 35, and sets 45 that belong to the sections of the first wafer W1 and the second wafer W2 corresponding to the chip region CR, and other components are omitted.

In preparing the second wafer W2, the second connection pads 42 are formed such that their bonding surfaces are at the fourth surface S4. More specifically, the center of each second connection pad 42 in plan view is offset from the center of the via 44 in plan view by distance a toward the edge of the second wafer W2 in the right direction of the drawing plane to form the second connection pad 42. Distance a, that is, the magnitude of vector V2, may be determined taking into account the amount by which the first wafer W1 expands, more specifically, the amount by which the first wafer W1 becomes larger than the second wafer W2. Each second connection pad 42 may be obtained, but not limited to, by stacking an insulating film 41 on the exposed surface of the second wiring layer 40, forming a hole h2 in the stacked insulating film 41 by known lithography and etching techniques, filling the hole h2 with copper by a plating method, and then removing excess copper by a chemical mechanical polishing (CMP) method and planarizing the exposed surface of the second wiring layer 40, for example.

As such, the offset of the center of the second connection pad 42 in plan view may be achieved by offsetting, in the lithography step that forms the hole h2, the imaging position of the exposure pattern from the originally intended imaging position in accordance with the direction and distance indicated by vector V2. That is, the exposure may be performed such that a plurality of exposure patterns within the wafer surface are offset toward the edge of the second wafer W2 in plan view from the originally intended imaging positions. Furthermore, the magnitude of the first distance may be set to be greater for an exposure pattern that is farther from the center of the second wafer W2. Here, the originally intended imaging position is the imaging position where the center of the second connection pad 42 in plan view coincides with the center of the via 44 in plan view.

The first wafer W1 and the second wafer W2 are placed opposed to each other with a gap therebetween such that their wiring layers face each other, and the wafers are positioned relative to each other. Then, the center portion of the first wafer W1, which is warped convexly toward the second wafer W2, is pressed, and the first wafer W1 is bonded to the second wafer W2 from the wafer center portion to obtain the state shown in FIG. 9A. At this time, of the first wafer W1 and the second wafer W2, at least the first wafer W1 expands in the radial direction. The amount of radial expansion of the first wafer W1 is greater than that of the second wafer W2. Here, in the second wafer W2, which is one of the first wafer W1 and the second wafer W2 that has a smaller radial expansion amount, the second connection pads 42 are offset toward the wafer edge direction in plan view in advance. Thus, even when the first wafer W1 expands more than the second wafer W2 in the radial direction, the second connection pad 42 is present at the location to which the first connection pad 32 moves as the first wafer W1 expands. As a result, the stacking of the first connection pad 32 and the second connection pad 42 is unlikely to be significantly misaligned.

### Main Advantageous Effects of Third Embodiment

The main advantageous effects of the third embodiment are described below. The photodetection device 1 according to the third embodiment also has the same advantageous effect as the photodetection device 1 according to the first embodiment described above.

### Fourth Embodiment

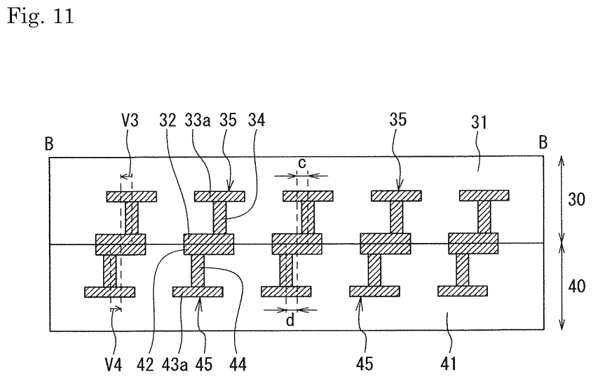

A fourth embodiment of the present technology shown in FIG. 11 is described below. A photodetection device 1 according to the fourth embodiment is a combination of the set 35 of the first embodiment and the set 45 of the third embodiment. The other configuration of the photodetection device 1 is basically the same as that of the photodetection device 1 of the above-described first embodiment. Components that have already been described are given the same reference numerals and their description are omitted. The sets 35 and 45 of one photodetection device 1 shown in FIG. 11 show a longitudinal cross-sectional structure of a chip region located at the same position on the wafer surface as the chip region CR of FIGS. 6A and 9B and a photodetection device 1 obtained by separating this chip region.

### <First Wiring Layer>

In all sets 35 of the first wiring layer (wiring layer) 30 in one photodetection device 1, the center of the first connection pad 32 in plan view is located at distance c to the left of the drawing plane from the center of the via 34 in plan view. The position of the center of the first connection pad 32 in plan view from the center of the via 34 in plan view is represented by vector V3 in the figure. The direction of vector V3 represents a first direction (the left direction of the drawing plane in the example of FIG. 11), and the magnitude of vector V3 represents a first distance (distance c in the example of FIG. 11).

### <Second Wiring Layer>

In all sets 45 of the second wiring layer (wiring layer) 40 in one photodetection device 1, the center of the second connection pad 42 in plan view is located at distance d to the right of the drawing plane from the center of the via 44 in plan view. The position of the center of the second connection pad 42 in plan view from the center of the via 44 in plan view is represented by vector V4 in the figure. The direction of vector V4 represents a second direction (the right direction of the drawing plane in the example of FIG. 11), and the magnitude of vector V4 represents a second distance (distance d in the example of FIG. 11).

The second direction, which is the direction of vector V4, is opposite to the first direction, which is the direction of vector V3, for example, a direction opposite to the first direction by 180 degrees. That is, in all sets 45 of the second wiring layer 40, the center of the second connection pad 42 is located at the second distance from the center of the via 44 in the second direction in plan view.

Regarding distances c and d, the distance (e.g., distance a) in a configuration in which the position of the connection pad is offset relative to the via only in one of the first wafer W1 and the second wafer W2 is divided into distance c and distance d (distance a=distance c+distance d). Although not limited to this, the distance in a configuration in which the position of the connection pad is offset relative to the via only in one of the first wafer W1 and the second wafer W2 may be evenly divided into distance c and distance d (distance c=distance d).

### Main Advantageous Effects of Fourth Embodiment

The main advantageous effects of the fourth embodiment are described below. The photodetection device 1 according to the fourth embodiment also has the same advantageous effect as the photodetection device 1 according to the first and third embodiments described above.

### Fifth Embodiment

A fifth embodiment of the present technology is described below. In the fifth embodiment, the chip regions of the third wafer W3 and the semiconductor chips 2 obtained by separating the chip regions are each equipped with a memory instead of the photodetection device 1 as a semiconductor device. The configurations of the sets 35 and 45 are the same as those of any of the first to fourth embodiments, and detailed description thereof is thus omitted in this embodiment.

In each of the chip regions of the third wafer W3 shown in FIG. 1B and the semiconductor chips 2 into which the chip regions are separated, integrated circuits forming memory cells of dynamic random access memory (DRAM) and driving logic circuits for driving the memory cells are fabricated. Although not limited to this, integrated circuits forming memory cells may be provided on the first wafer W1, and integrated circuits forming drive logic circuits may be provided on the second wafer W2.

### Main Advantageous Effects of Fifth Embodiment

The main advantageous effects of the fifth embodiment are described below. The photodetection device 1 according to the fifth embodiment also has the same advantageous effect as the photodetection device 1 according to any of the first to fourth embodiments.

### Sixth Embodiment

### <1. Example of Application to Electronic Equipment>

Electronic equipment 100 shown in FIG. 12 is now described. The electronic equipment 100 includes a solid-state imaging device 101, an optical lens 102, a shutter device 103, a drive circuit 104, and a signal processing circuit 105. The electronic equipment 100 is, but not limited to, electronic equipment such as a camera, for example. The electronic equipment 100 includes the above-described photodetection device 1 as a solid-state imaging device 101.

The optical lens (optical system) 102 forms an image of imaging light (incident light 106) from a subject on the imaging surface of the solid-state imaging device 101. This causes signal charges to be accumulated in the solid-state imaging device 101 for a certain period of time. The shutter device 103 controls a light application period and a light blocking period for the solid-state imaging device 101. The drive circuit 104 supplies a drive signal that controls the transfer operation of the solid-state imaging device 101 and the shutter operation of the shutter device 103. Signal transfer of the solid-state imaging device 101 is performed in response to a drive signal (timing signal) supplied from a drive circuit 104. The signal processing circuit 105 performs various types of signal processing on the signals (pixel signals) output from the solid-state imaging device 101. The video signal that has undergone signal processing is stored in a storage medium such as a memory, or is output to a monitor. The electronic equipment 100 includes a memory according to the fifth embodiment as a storage medium.

This configuration can limit significant misalignment of the first connection pads 32 and the second connection pads 42 in the solid-state imaging device 101 of the electronic equipment 100, thereby improving the reliability of the electronic equipment 100.

The electronic equipment 100 is not limited to a camera, and may be other electronic equipment. For example, it may be an imaging device of a camera module for a mobile device such as a mobile phone.

Furthermore, the electronic equipment 100 may include, as the solid-state imaging device 101, a photodetection device 1 according to any of the first to fourth embodiments and their modifications, or a photodetection device 1 according to a combination of at least two of the first to fourth embodiments and their modifications.

### <2. Example of Application to Moving Object>

The technology according to the present disclosure (present technology) is applicable to various products. For example, the technology according to the present disclosure may be embodied as a device that is mounted on a moving object of any types such as vehicles, electric vehicles, hybrid electric vehicles, motorcycles, bicycles, personal mobility devices, airplanes, drones, ships, and robots.

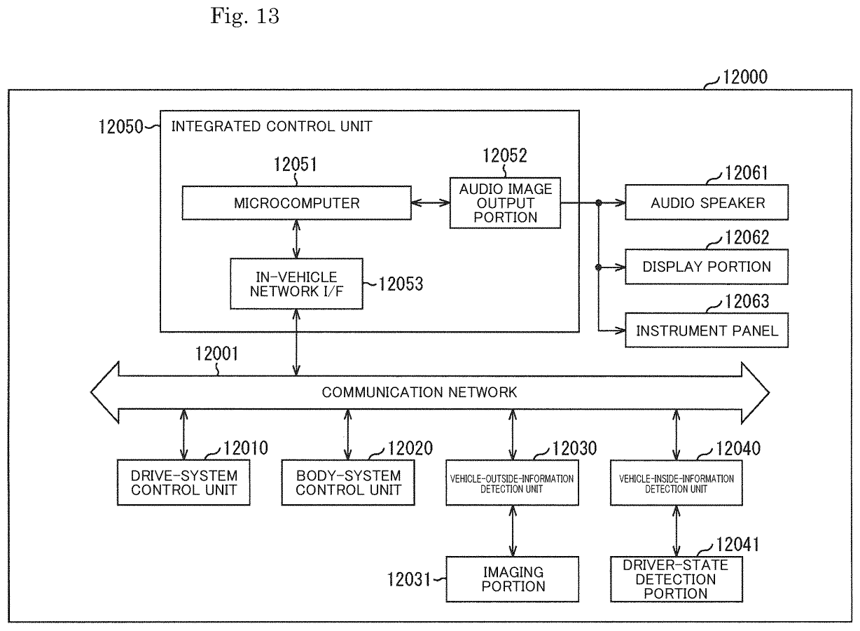

FIG. 13 is a block diagram schematically showing an example of the configuration of a vehicle control system, which is an example of a moving-object control system to which the technology according to the present disclosure is applicable.

A vehicle control system 12000 includes a plurality of electronic control units connected via a communication network 12001. In the example shown in FIG. 13, the vehicle control system 12000 includes a drive-system control unit 12010, a body-system control unit 12020, a vehicle-outside-information detection unit 12030, a vehicle-inside-information detection unit 12040, and an integrated control unit 12050. Additionally, as functional configurations of the integrated control unit 12050, a microcomputer 12051, an audio image output portion 12052, and an in-vehicle network interface (I/F) 12053 are shown.

The drive-system control unit 12010 controls the operation of the devices related to the drive system of the vehicle according to various programs. For example, the drive-system control unit 12010 functions as a controller for a driving-force generator for generating driving force of the vehicle, such as an internal combustion engine or a driving motor, a driving-force transmission mechanism for transmitting the driving force to the wheels, a steering mechanism for adjusting the steering angle of the vehicle, a braking device for generating braking force of the vehicle, and the like.

The body-system control unit 12020 controls the operation of various devices mounted on the vehicle body according to various programs. For example, the body-system control unit 12020 functions as a controller for a keyless entry system, a smart key system, a power window device, and various lights such as headlights, back-up lights, brake lights, blinkers, and fog lights. In this case, the radio waves transmitted from a portable device that substitutes for the key, or signals of various switches may be input to the body-system control unit 12020. The body-system control unit 12020 receives inputs of these radio waves or signals and controls a door lock device, the power window device, lights, and the like of the vehicle.

The vehicle-outside-information detection unit 12030 detects information on the outside of the vehicle equipped with the vehicle control system 12000. For example, the imaging portion 12031 is connected to the vehicle-outside-information detection unit 12030. The vehicle-outside-information detection unit 12030 causes the imaging portion 12031 to capture an image of the outside of the vehicle and receives the captured image. Based on the received image, the vehicle-outside-information detection unit 12030 may perform detection processing or distance detection processing with respect to objects such as a person, a vehicle, an obstacle, a sign, or characters on the road surface.

The imaging portion 12031 is an optical sensor that receives light and outputs an electric signal according to the amount of the light received. The imaging portion 12031 can output an electric signal as an image or as distance measurement information. The light received by the imaging portion 12031 may be visible light or invisible light such as infrared rays.

The vehicle-inside-information detection unit 12040 detects information on the inside of the vehicle. For example, a driver-state detection portion 12041, which detects the driver's state, is connected to the vehicle-inside-information detection unit 12040. The driver-state detection portion 12041 includes, for example, a camera that captures an image of the driver, and the vehicle-inside-information detection unit 12040 may determine the degree of fatigue or concentration of the driver, or determine whether the driver is dozing, based on the detection information input from the driver-state detection portion 12041.

Based on the information on the inside and outside the vehicle obtained by the vehicle-outside-information detection unit 12030 or the vehicle-inside-information detection unit 12040, the microcomputer 12051 can calculate the control target values of the driving-force generator, the steering mechanism, or the braking device and output a control command to the drive-system control unit 12010. For example, the microcomputer 12051 can perform cooperative control for the purpose of achieving an advanced driver assistance system (ADAS) function including vehicle collision avoidance and impact relief, driving with headway control based on the vehicle-to-vehicle distance, constant speed driving, vehicle collision warning, vehicle lane deviation warning, and the like.

Based on the information on the surroundings of the vehicle obtained by the vehicle-outside-information detection unit 12030 or the vehicle-inside-information detection unit 12040, the microcomputer 12051 can control the driving-force generator, the steering mechanism, the braking device, and the like to perform a cooperative control for the purpose of automated driving or the like, in which the vehicle travels autonomously without depending on the maneuvering by the driver.

The microcomputer 12051 can also output a control command to the body-system control unit 12020 based on the information on the outside of the vehicle obtained by the vehicle-outside-information detection unit 12030. For example, the microcomputer 12051 controls the headlights according to the position of the preceding vehicle or an oncoming vehicle detected by the vehicle-outside-information detection unit 12030, and performs cooperative control for the purpose of antiglare, such as switching the high beam to the low beam.

The audio image output portion 12052 transmits an output signal of at least one of audio and an image to an output device capable of visually or audibly issuing information to the passenger or to the outside of the vehicle. In the example of FIG. 13, an audio speaker 12061, a display portion 12062, and an instrument panel 12063 are illustrated as examples of output devices. The display portion 12062 may include, for example, at least one of an onboard display and a head up display.

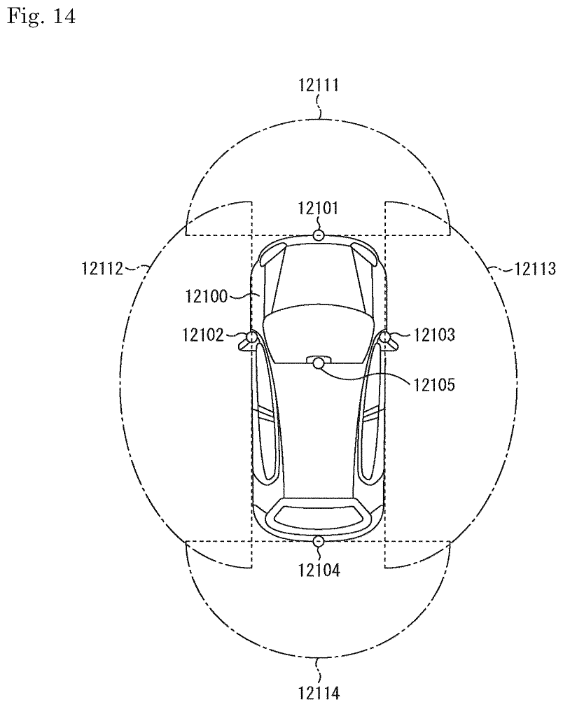

FIG. 14 is a diagram showing an example of installation positions of the imaging portion 12031.

In FIG. 14, the vehicle 12100 has imaging portions 12101, 12102, 12103, 12104, and 12105 as the imaging portion 12031.

The imaging portions 12101, 12102, 12103, 12104, and 12105 are provided at positions such as the front nose, side mirrors, rear bumper, back door, and the upper part of the windshield in the passenger compartment of the vehicle 12100. The imaging portion 12101 provided in the front nose and the imaging portion 12105 provided in the upper part of the windshield in the passenger compartment mainly obtain images of the front side of the vehicle 12100. The imaging portions 12102 and 12103 provided in the side mirrors mainly obtain images of the sides of the vehicle 12100. The imaging portion 12104 provided in the rear bumper or the back door mainly obtains images of the rear of the vehicle 12100. The images of the front side obtained by the imaging portions 12101 and 12105 are mainly used to detect the preceding vehicle, a pedestrian, an obstacle, a traffic light, a traffic sign, a lane, or the like.

In addition, FIG. 14 shows an example of the image ranges of the imaging portions 12101 to 12104. The image range 12111 indicates the image range of the imaging portion 12101 provided in the front nose, the image ranges 12112 and 12113 indicate the image ranges of the imaging portions 12102 and 12103, respectively, provided in the side mirrors, and the image range 12114 indicates the image range of the imaging portion 12104 provided in the rear bumper or the back door. For example, by superimposing the image data captured by the imaging portions 12101 to 12104, a bird's-eye view image of the vehicle 12100 as viewed from above can be obtained.

At least one of the imaging portions 12101 to 12104 may have a function of obtaining distance information. For example, at least one of the imaging portions 12101 to 12104 may be a stereo camera composed of a plurality of imaging elements, or may be an imaging element having pixels for phase difference detection.

For example, based on the distance information obtained from the imaging portions 12101 to 12104, the microcomputer 12051 determines the distances to three-dimensional objects located within the image ranges 12111 to 12114, and the temporal changes in these distances (the speed relative to the vehicle 12100). This allows for the extraction, as the preceding vehicle, of the closest three-dimensional object on the traveling path of the vehicle 12100 that travels at a predetermined speed (for example, 0 km/h or more) in substantially the same direction as the vehicle 12100. Furthermore, the microcomputer 12051 can preset the vehicle-to-vehicle distance to be maintained to the preceding vehicle, and can perform automatic braking control (including stop control in driving with headway control), automatic acceleration control (including start control in driving with headway control), and the like. In this manner, it is possible to perform cooperative control for the purpose of automated driving or the like, in which the vehicle travels autonomously without depending on the maneuvering by the driver.

For example, based on the distance information obtained from the imaging portions 12101 to 12104, the microcomputer 12051 can extract and classify three-dimensional object data on three-dimensional objects into motorcycle, standard-sized vehicle, large vehicle, pedestrian, electric pole, and other three-dimensional object, and use it for automatic obstacle avoidance. For example, the microcomputer 12051 classifies obstacles around the vehicle 12100 into obstacles that can be visually recognized by the driver of the vehicle 12100, and obstacles that are difficult to visually recognize. The microcomputer 12051 determines the collision risk, which indicates the risk of collision with each obstacle. When the collision risk is equal to or higher than the set value and therefore there is a possibility of collision, the microcomputer 12051 outputs an alert to the driver via the audio speaker 12061 or the display portion 12062, or performs forced deceleration and avoidance steering via the drive-system control unit 12010 to provide driving support for collision avoidance.

At least one of the imaging portions 12101 to 12104 may be an infrared camera that detects infrared rays. For example, the microcomputer 12051 can recognize a pedestrian by determining whether a pedestrian is present in the images captured by the imaging portions 12101 to 12104. Such pedestrian recognition includes, for example, a step of extracting feature points in the images captured by the imaging portions 12101 to 12104, which serve as infrared cameras, and a step of determining whether an object is a pedestrian by performing pattern matching processing on a series of feature points indicating the contours of the object. When the microcomputer 12051 determines that a pedestrian is present in the images captured by the imaging portions 12101 to 12104 and recognizes the pedestrian, the audio image output portion 12052 controls the display portion 12062 to display a rectangular contour line superimposed on the recognized pedestrian for highlighting. Furthermore, the audio image output portion 12052 may control the display portion 12062 so as to display, at a desired position, an icon or the like indicating the pedestrian.

The example of the vehicle control system to which the technology according to the present disclosure is applicable is described above. The technology according to the present disclosure is applicable to, for example, the imaging portion 12031 in the configuration described above. Specifically, the photodetection device 1 of FIG. 5 may be applied to the imaging portion 12031. By applying the technology of the present disclosure to the imaging portion 12031, it is possible to limit significant misalignment of the stacking of the first connection pad 32 and the second connection pad 42, thereby improving the reliability of the imaging portion 12031.

### <3. Example of Application to Endoscopic Surgery System>

The technology according to the present disclosure (present technology) is applicable to various products. For example, the technology according to the present disclosure may be applied to endoscopic surgery systems.

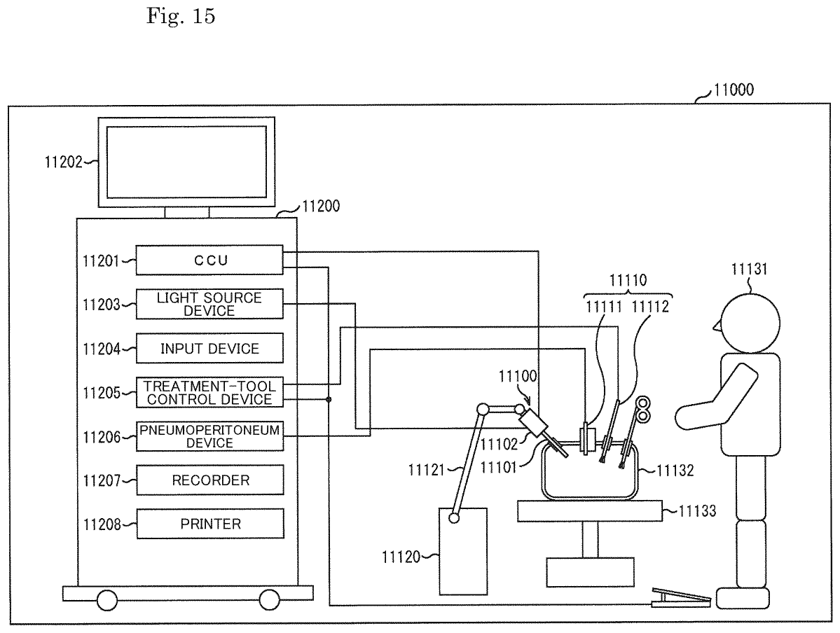

FIG. 15 is a diagram schematically showing an example of the configuration of an endoscopic surgery system to which the technology according to the present disclosure (present technology) is applicable.

FIG. 15 illustrates a situation in which an operator (doctor) 11131 is performing surgery on a patient 11132 on a patient bed 11133 using an endoscopic surgery system 11000. As shown, the endoscopic surgery system 11000 is composed of an endoscope 11100, other surgical tools 11110, such as a pneumoperitoneum tube 11111 and an energy treatment tool 11112, a support arm device 11120 that supports the endoscope 11100, and a cart 11200 equipped with various devices for endoscopic surgery.

The endoscope 11100 is composed of a lens tube 11101, which has a region extending from its distal end over a predetermined length that is to be inserted in a body cavity of the patient 11132, and a camera head 11102 connected to the proximal end of the lens tube 11101. In the illustrated example, the endoscope 11100 configured as a so-called rigid endoscope having the rigid lens tube 11101 is illustrated, but the endoscope 11100 may be configured as a so-called flexible endoscope having a flexible lens tube.

An opening in which an objective lens is fitted is provided at the distal end of the lens tube 11101. A light source device 11203 is connected to the endoscope 11100, and the light generated by the light source device 11203 is guided to the distal end of the lens tube by a light guide, which extends inside the lens tube 11101, and applied toward the observation target in the body cavity of the patient 11132 through the objective lens. The endoscope 11100 may be a forward-viewing endoscope, a forward-oblique viewing endoscope, or a side-viewing endoscope.

An optical system and an imaging element are provided inside the camera head 11102, and the reflected light (observation light) from the observation target is focused on the imaging element by the optical system. The observation light is photoelectrically converted by the imaging element, and an electric signal corresponding to the observation light, that is, an image signal corresponding to the observation image is generated. The image signal is transmitted to a camera control unit (CCU) 11201 as RAW data.

The CCU 11201 may be composed of a central processing unit (CPU) or a graphics processing unit (GPU), for example, and comprehensively controls the operations of the endoscope 11100 and the display device 11202. Additionally, the CCU 11201 receives an image signal from the camera head 11102, and the image signal is subjected to various image processing for displaying an image based on the image signal, such as development processing (demosaicing).

Under the control of the CCU 11201, the display device 11202 displays an image based on the image signal on which the image processing is performed by the CCU 11201.

The light source device 11203 may be composed of a light source such as a light emitting diode (LED), and supplies illumination light to the endoscope 11100 when capturing an image of the surgical site and the like.

An input device 11204 is an input interface to the endoscopic surgery system 11000. The user can input various types of information and instructions to the endoscopic surgery system 11000 via the input device 11204. For example, the user inputs an instruction to change the photographing conditions (the type of illumination light, magnification, focal length, etc.) of the endoscope 11100.

A treatment-tool control device 11205 controls the driving of the energy treatment tool 11112 for tissue cauterization, incision, or sealing of blood vessels, for example. To expand a body cavity of the patient 11132 for the purpose of securing the field of view of the endoscope 11100 and the work space for the operator, a pneumoperitoneum device 11206 sends gas into the body cavity through the pneumoperitoneum tube 11111. A recorder 11207 is a device capable of recording various types of information relating to the surgery. A printer 11208 is a device capable of printing various types of information relating to the surgery in various formats such as text, images, and graphs.

The light source device 11203 that supplies illumination light to the endoscope 11100 when capturing an image of the surgical site is composed of, for example, an LED, a laser light source, or a white light source composed of a combination thereof. When a white light source is composed of a combination of RGB laser light sources, the output intensity and output timing of each color (each wavelength) can be controlled with high accuracy, allowing the light source device 11203 to adjust the white balance of the captured image. In this case, the laser light from each of the RGB laser light sources may be applied to the observation target in a time-sharing manner, and the driving of the imaging element of the camera head 11102 may be controlled in synchronization with the application timing. This allows for the capturing of images corresponding to R, G, and B in a time-sharing manner. According to this method, a color image can be obtained without providing a color filter on the imaging element.

The driving of the light source device 11203 may be controlled so as to change the intensity of the output light at predetermined time intervals. By controlling the driving of the imaging element of the camera head 11102 in synchronization with the timing of changing the light intensity to obtain images in a time-sharing manner and by combining these images, high dynamic range images can be generated without so-called underexposure and overexposure.

Furthermore, the light source device 11203 may be configured to be able to supply light in a predetermined wavelength band that enables special light imaging. In special light imaging, so-called narrow-band imaging, for example, is performed that uses the wavelength dependency of the light absorption of body tissues and captures images of a predetermined tissue, such as a blood vessel in the mucous membrane surface layer, with high contrast by applying light in a narrower band than the illumination light in normal imaging (that is, white light). Alternatively, in special light imaging, fluorescence imaging may be performed in which an image is obtained using the fluorescence generated by applying excitation light. In fluorescence imaging, body tissue is irradiated with excitation light to observe the fluorescence from the body tissue (autofluorescence endoscopy), or a reagent such as indocyanine green (ICG) is locally injected into a body tissue, which is then irradiated with excitation light corresponding to the fluorescence wavelength of the reagent to obtain a fluorescence image. The light source device 11203 may be configured to be capable of supplying narrow-band light and/or excitation light for such special light imaging.

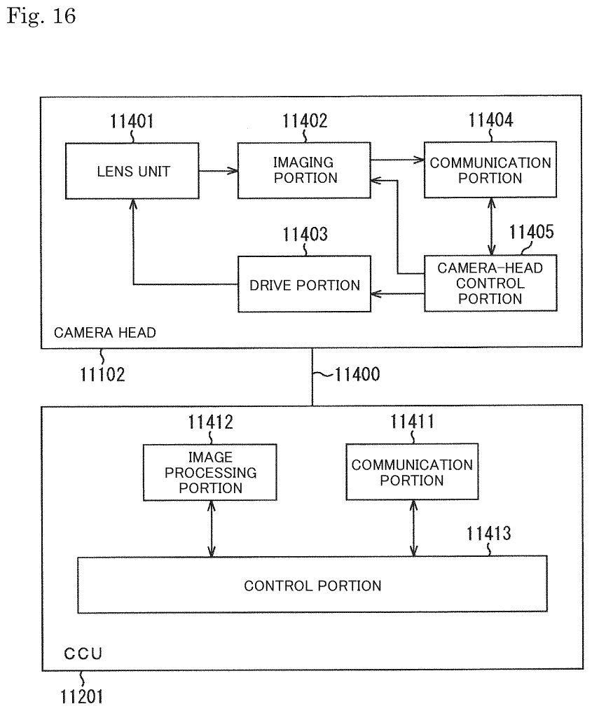

FIG. 16 is a block diagram showing an example of the functional configuration of the camera head 11102 and the CCU 11201 shown in FIG. 15.

The camera head 11102 includes a lens unit 11401, an imaging portion 11402, a drive portion 11403, a communication portion 11404, and a camera-head control portion 11405. The CCU 11201 has a communication portion 11411, an image processing portion 11412, and a control portion 11413. The camera head 11102 and the CCU 11201 are connected by a transmission cable 11400 so as to communicate with each other.

The lens unit 11401 is an optical system provided at a connection portion with the lens tube 11101. The observation light taken in through the distal end of the lens tube 11101 is guided to the camera head 11102 and incident on the lens unit 11401. The lens unit 11401 is composed of a combination of a plurality of lenses including a zoom lens and a focus lens.

The imaging portion 11402 is composed of an imaging element. The imaging element composing the imaging portion 11402 may be one element (so-called single-chip type) or a plurality of elements (so-called multi-chip type). When the imaging portion 11402 is of a multi-chip type, each imaging element may generate an image signal corresponding to one of R, G, and B, and a color image may be obtained by combining these signals. Alternatively, the imaging portion 11402 may be configured to have a pair of imaging elements each provided to obtain an image signal for one of the right eye and the left eye to achieve three-dimensional (3D) display. The 3D display enables the operator 11131 to more accurately identify the depth of the biological tissue in the surgical site. When the imaging portion 11402 is of a multi-chip type, a plurality of lens units 11401 may be provided corresponding to the imaging elements.

The imaging portion 11402 does not necessarily have to be provided in the camera head 11102. For example, the imaging portion 11402 may be provided inside the lens tube 11101 adjacent to and behind the objective lens.

The drive portion 11403 is composed of an actuator, and moves the zoom lens and the focus lens of the lens unit 11401 by a predetermined distance along the optical axis under the control of the camera-head control portion 11405. As a result, the magnification and focus of the image captured by the imaging portion 11402 can be adjusted as appropriate.

The communication portion 11404 is composed of a communication device for transmitting and receiving various types of information to and from the CCU 11201. The communication portion 11404 transmits the image signal obtained from the imaging portion 11402 as RAW data to the CCU 11201 via the transmission cable 11400.

The communication portion 11404 also receives a control signal for controlling the driving of the camera head 11102 from the CCU 11201 and feeds the control signal to the camera-head control portion 11405. The control signal contains information about the photographing conditions, such as information for specifying the frame rate of the captured image, information for specifying the exposure value for capturing images, and/or information for specifying the magnification and focus of the captured image.

The above-mentioned photographing conditions such as frame rate, exposure value, magnification, and focus may be specified by the user as required, or automatically set by the control portion 11413 of the CCU 11201 based on the obtained image signal. In the latter case, the endoscope 11100 has a so-called auto exposure (AE) function, an autofocus (AF) function, and an auto white balance (AWB) function.

The camera-head control portion 11405 controls the driving of the camera head 11102 based on the control signal from the CCU 11201 received via the communication portion 11404.

The communication portion 11411 is composed of a communication device for transmitting and receiving various types of information to and from the camera head 11102. The communication portion 11411 receives an image signal transmitted from the camera head 11102 via the transmission cable 11400.

The communication portion 11411 also transmits a control signal for controlling the driving of the camera head 11102 to the camera head 11102. Image signals and control signals can be transmitted by telecommunications, optical communication, or the like.

The image processing portion 11412 performs various types of image processing on the image signal, which is the RAW data transmitted from the camera head 11102.

The control portion 11413 performs various controls relating to the capturing of images of the surgical site and the like by the endoscope 11100 and the display of the images obtained by capturing images of the surgical site and the like. For example, the control portion 11413 generates a control signal for controlling the driving of the camera head 11102.

The control portion 11413 also causes the display device 11202 to display the captured image of the surgical site and the like, based on the image signal on which the image processing is performed by the image processing portion 11412. At this time, the control portion 11413 may identify various objects in the captured image using various image recognition techniques. For example, by detecting the shape of the edge and color of an object in the captured image, the control portion 11413 can identify a surgical tool such as forceps, a specific biological site, bleeding, and mist in the use of the energy treatment tool 11112, for example. When displaying the captured image on the display device 11202, the control portion 11413 may superimpose various types of information that aids the surgery on the image of the surgical site, using the result of identification. By providing the operator 11131 with the superimposed information that aids the surgery, the burden on the operator 11131 can be reduced, and the operator 11131 can reliably perform the surgery.

The transmission cable 11400 connecting the camera head 11102 and the CCU 11201 may be an electric signal cable that enables electric signal communication, an optical fiber that enables optical communication, or a composite cable of these.

In the illustrated example, the communication is performed by wire using the transmission cable 11400, but the communication between the camera head 11102 and the CCU 11201 may be performed wirelessly.

The above is an example of an endoscopic surgery system to which the technology according to the present disclosure is applicable. The technology according to the present disclosure is applicable to the imaging portion 11402 of the camera head 11102, for example, in the configuration described above. Specifically, the photodetection device 1 of FIG. 5 may be applied to the imaging portion 11402. By applying the technology of the present disclosure to the imaging portion 11402, it is possible to limit significant misalignment of the stacking of the first connection pad 32 and the second connection pad 42, thereby improving the reliability of the imaging portion 11402.

Although an endoscopic surgery system has been described as an example, the technology according to the present disclosure may also be applied to other systems, such as a microsurgery system.

### OTHER EMBODIMENTS

As described above, the present technology has been described with reference to the first to sixth embodiments, but the descriptions and drawings forming a part of this disclosure should not be understood as limiting the present technology. From this disclosure, various alternative embodiments, implementations, and operational technology will become apparent to those skilled in the art.

For example, it is also possible to combine the technical ideas described in the first to sixth embodiments with each other. For example, the first wiring layer 30 according to the second embodiment described above includes vias 34 that are offset in the first direction. This technical idea may be applied to the photodetection device 1 according to the third embodiment or the fourth embodiment, for example, and various combinations are possible in line with each technical idea.

Also, the present technology is applicable to photodetection devices in general, including not only solid-state imaging devices as the image sensors described above, but also distance measurement sensors that measure distance, also known as time-of-flight (ToF) sensors. A distance measurement sensor is a sensor that emits illumination light toward an object, detects the reflection light that is the illumination light reflected off the surface of the object, and calculates the distance to the object based on the flight time from when the illumination light is emitted to when the reflection light is received. As the structure of the distance measurement sensor, the above-mentioned bonded structure may be used.

The present technology is also applicable to the bonding of wafers in a semiconductor device having three or more wafers. More specifically, the present technology is applicable to the bonding of at least two wafers of three or more wafers. Furthermore, the materials of the components listed above may include additives or impurities, for example.

It should be noted that the effects described in this specification are merely examples and are not limiting, and other effects may also occur.

The present technology may be configured as follows.

(1)

A semiconductor device comprising:
two semiconductor layers; and
a wiring layer on one side in a stacking direction and a wiring layer on the other side in the stacking direction that are interposed between the semiconductor layers, each including a plurality of sets located in an insulating film, the sets each including a connection pad, a wiring line, and a via connecting the connection pad to the wiring line, and that are electrically connected to each other by bonding bonding surfaces of the connection pads to each other, wherein
in all the sets in the wiring layer on one side in the stacking direction, a center of the connection pad is located at a first distance from a center of the via in a first direction.
   (2)

The semiconductor device according to (1), wherein the first distance is set to be greater than a distance between a center of the connection pad and a center of the via in plan view of each of the sets in the wiring layer on the other side in the stacking direction.

(3)

The semiconductor device according to (1), wherein in all the sets in the wiring layer on the other side in the stacking direction, a center of the connection pad is located at a second distance from a center of the via in a second direction opposite to the first direction in plan view.

(4)

The semiconductor device according to (3), wherein the second distance is equal to the first distance.

(5)

The semiconductor device according to any one of (1) to (4), wherein one of the two semiconductor layers includes a photoelectric conversion portion capable of performing photoelectric conversion on incident light.

(6)

Electronic equipment comprising
a photodetection device and an optical system configured to form an image of imaging light from a subject on the photodetection device, wherein
the photodetection device includes:
two semiconductor layers; and
a wiring layer on one side in a stacking direction and a wiring layer on the other side in the stacking direction that are interposed between the semiconductor layers, each including a plurality of sets located in an insulating film, the sets each including a connection pad, a wiring line, and a via connecting the connection pad to the wiring line, and that are electrically connected to each other by bonding bonding surfaces of the connection pads to each other, in all the sets in the wiring layer on one side in the stacking direction, a center of the connection pad is located at a first distance from a center of the via in a first direction, and
one of the two semiconductor layers includes a photoelectric conversion portion capable of performing photoelectric conversion on incident light.
   (7)

A wafer comprising:1
a laminate including a semiconductor layer and a wiring layer stacked on the semiconductor layer; and
a plurality of chip regions that are arranged in a matrix in plan view on the laminate, each of the chip regions including an integrated circuit fabricated therein, wherein
the wiring layer includes, for each of the chip regions, a plurality of sets that are provided in an insulating film and form a part of the integrated circuit, each of the sets including a connection pad, a wiring line, and a via connecting the connection pad to the wiring line,
for each of the chip regions, a center of the connection pad is at a first distance from a center of the via in a first direction, and
the first direction is a direction toward a center or an edge of the laminate in plan view.
   (8)

The wafer according to (7), wherein a magnitude of the first distance is greater for the chip region that is farther from the center of the laminate.

The scope of the present technology is not limited to the exemplary embodiments shown and described, but includes all embodiments that achieve equivalent effects to those intended by the present technology. Moreover, the scope of the technology is not limited to the combination of inventive features defined by the claims, but may be defined by any desired combination of particular features among all the respective disclosed features.

### REFERENCE SIGNS LIST

1 Photodetection device
2 Semiconductor chip
2A Pixel region
2B Peripheral region
3 Pixel
4 Vertical drive circuit
5 Column signal processing circuit
6 Horizontal drive circuit
7 Output circuit
8 Control circuit
10 Pixel drive line
11 Vertical signal line
12 Horizontal signal line
13 Logic circuit
15 Readout circuit
20 First semiconductor layer
21 Photoelectric conversion portion (semiconductor region)
30 First wiring layer
31 Insulating film
32 First connection pad
33, 33a Wiring line
34, 44 Via
35, 45 Set
40 Second wiring layer
41 Insulating film
42 Second connection pad
43, 43a Wiring line
50 Second semiconductor layer
61 Insulating film
62 Color filter
100 Electronic equipment
102 Optical system (optical lens)
CC, CL, CR, LL, UR Chip region
h1, h2 Hole
PAD, VIA Chip region
V1, V2, V3, V4 Vector
W1 First wafer
W2 Second wafer
W3 Third wafer

What is claimed is:

1. A semiconductor device, comprising:
two semiconductor layers; and
a wiring layer on one side in a stacking direction and a wiring layer on the other side in the stacking direction that are interposed between the semiconductor layers, each including a plurality of sets located in an insulating film, the sets each including a connection pad, a wiring line, and a via connecting the connection pad to the wiring line, and that are electrically connected to each other by bonding bonding surfaces of the connection pads to each other, wherein
in all the sets in the wiring layer on one side in the stacking direction, a center of the connection pad is located at a first distance from a center of the via in a first direction.

2. The semiconductor device according to claim 1, wherein the first distance is set to be greater than a distance between a center of the connection pad and a center of the via in plan view of each of the sets in the wiring layer on the other side in the stacking direction.

3. The semiconductor device according to claim 1, wherein in all the sets in the wiring layer on the other side in the stacking direction, a center of the connection pad is located at a second distance from a center of the via in a second direction opposite to the first direction in plan view.

4. The semiconductor device according to claim 3, wherein the second distance is equal to the first distance.

5. The semiconductor device according to claim 1, wherein one of the two semiconductor layers includes a photoelectric conversion portion capable of performing photoelectric conversion on incident light.

6. Electronic equipment, comprising
a photodetection device and an optical system configured to form an image of imaging light from a subject on the photodetection device, wherein
the photodetection device includes:
two semiconductor layers; and
a wiring layer on one side in a stacking direction and a wiring layer on the other side in the stacking direction that are interposed between the semiconductor layers, each including a plurality of sets located in an insulating film, the sets each including a connection pad, a wiring line, and a via connecting the connection pad to the wiring line, and that are electrically connected to each other by bonding bonding surfaces of the connection pads to each other,
in all the sets in the wiring layer on one side in the stacking direction, a center of the connection pad is located at a first distance from a center of the via in a first direction, and
one of the two semiconductor layers includes a photoelectric conversion portion capable of performing photoelectric conversion on incident light.

7. A wafer, comprising:
a laminate including a semiconductor layer and a wiring layer stacked on the semiconductor layer; and
a plurality of chip regions that are arranged in a matrix in plan view on the laminate, each of the chip regions including an integrated circuit fabricated therein, wherein
the wiring layer includes, for each of the chip regions, a plurality of sets that are provided in an insulating film and form a part of the integrated circuit, each of the sets including a connection pad, a wiring line, and a via connecting the connection pad to the wiring line,
for each of the chip regions, a center of the connection pad is at a first distance from a center of the via in a first direction, and
the first direction is a direction toward a center or an edge of the laminate in plan view.

8. The wafer according to claim 7, wherein a magnitude of the first distance is greater for the chip region that is farther from the center of the laminate.
